(19) United States
(12) Patent Application Publication
(10) Pub. No.: US 2022/0341996 A1
(43) Pub. Date: Oct. 27, 2022

(54) METHOD FOR PREDICTING FAULTS IN POWER PACK OF COMPLEX EQUIPMENT BASED ON A HYBRID PREDICTION MODEL

(71) Applicant: DALIAN UNIVERSITY OF TECHNOLOGY, Dalian, Laoning (CN)

(72) Inventors: Ximing SUN, Dalian, Liaoning (CN); Aina WANG, Dalian, Liaoning (CN); Yingshun LI, Dalian, Liaoning (CN); Chongquan ZHONG, Dalian, Liaoning (CN)

(21) Appl. No.: 17/311,931

(22) PCT Filed: Jan. 20, 2021
(86) PCT No.: PCT/CN2021/072780

§ 371 Date: Jun. 8, 2021

(30) Foreign Application Priority Data
Jan. 11, 2021 (CN) 202110029485.7

(51) Int. Cl. G01R 31/367; G06N 3/08

(52) U.S. Cl. CPC G01R 31/367; G06N 3/08

(57) ABSTRACT

A method for predicting faults in power pack of complex equipment based on a hybrid prediction model is provided. The method includes steps of analyzing the typical faults of the power pack of complex equipment, extracting the core set of attributes therein, decomposing the time series of the power pack into a linear part and a non-linear part, using an Autoregressive Integrated Moving Average model to forecast the linear part, using an Artificial Neural Network model to forecast the residual obtained, and the predictions of the power pack are obtained by summing the predictions of the non-linear component with the linear component. The method further includes using the hybrid prediction model and the parallel parameters of the core attributes in combination with the upper and lower limits to obtain information on the operation status of the power pack.

### TECHNICAL FIELD

The present invention belongs to the technical field of complex equipment failure prediction, in particular, it relates to a method for predicting faults in power pack of complex equipment based on a hybrid prediction model, in particular, it relates to the operating data under steady state conditions of complex equipment and the method for predicting faults in power pack of complex equipment based on a hybrid prediction model using ARIMA combined with ANN.

### BACKGROUND

Large-scale equipment, due to its complex structure, can cause huge losses once a failure occurs. Therefore, there is an urgent need to improve the reliability, repairability and safety of complex equipment systems. However, the current fault diagnosis research is mainly focused on the “current” operating state, while there is a lack of research on the system fault prediction and health management. The field of complex equipment tends to be more and more intelligent, integrated and digital, and the mechanisms of the components are complex and highly interrelated. When a fault occurs, it is unable to determine the location and cause of the equipment fault in an efficient and timely manner. At present, there are still two main problems in solving the complex equipment prediction problems, (1) The single prediction model itself often has some shortcomings and cannot achieve the purpose of effective prediction; (2) A single operating parameter suffers from the problem of reflecting insufficient information to make accurate prediction.

### SUMMARY

To address the above limitations, the present invention provides a method for predicting faults in power pack of complex equipment based on a hybrid prediction model. On the one hand, a high precision hybrid prediction model based on ARIMA combined with ANN is proposed for monitoring the future development trend of key parameters of complex equipment power pack, forecasting the operational state of the power pack on the base of the hybrid prediction model and the parallel parameters for core attributes, it provides a basis for the comprehensive monitoring of the future operating status of complex equipment. On the other hand, establishing a procedure to monitor the future state of complex equipment power pack to guide the implementation of the prediction of the operating state of complex equipment.

In order to achieve the above objectives, the present invention uses the following technical solutions.

A method for predicting faults in power pack of complex equipment based on a hybrid prediction model, the prediction method being directed at operational data under steady-state conditions of the complex equipment.

The hybrid prediction model is a fault prediction model consisting of a combination of the Autoregressive Integrated Moving Average (ARIMA) model and Artificial Neural Network (ANN) model.

The ARIMA model is used to forecast the time series with a linear variation pattern of power pack.

The ANN model is used to forecast the time series with a non-linear pattern of variation of power pack.

The hybrid prediction model integrating the predictions of time series with a linear pattern of variation of power pack and the predictions of time series with a non-linear pattern of variation of power pack, and using parallel parameters of the core attributes for condition monitoring.

Comprising steps of:

Decomposing the original time series of the power pack into a linear part and a nonlinear part, using the ARIMA model to forecast the linear part and obtain predictions, and the difference between the original time series of the power pack and the linear predictions is made to obtain the residual e(t) which containing the nonlinear change pattern; using the ANN model to forecast the e(t) and obtain predictions. The predictions of the power pack are obtained by summing the predictions of the non-linear component with the linear component.

S1: Analyzing the power pack failures and extracting the core set of attributes.

S1.1: Establishing an evaluation indicator system for the set of attributes contained in the power pack of the complex equipment.

Complex equipment containing a power pack, a CPU board, a KZB board, an I/O board, an ADA board, an angular velocity sensor, a crosswind sensor and a tilt sensor.

S1.2: Using a rough set-based difference matrix to analyze the correlations between attributes and attributes approximation.

S1.2.1: Calculating the difference matrix M(T) based on the definition of the difference matrix.

S1.2.2: Calculating the difference function ƒM(T) based on the obtained difference matrix M(T).

S1.3: Obtaining the core set of attributes based on the minimum disjunction paradigm.

According to the difference function ƒM(T), using the minimal disjunction paradigm to reduce the attributes and obtain the core set of attributes.

Calculating the upper and lower limits of the core set of attributes extracted by the attribute reduction method of the rough set based difference matrix described above, upper limit=standard value+one tenth of the standard value and lower limit=standard value-one tenth of the standard value.

S2: Using ARIMA model to forecast the time series with linear variation pattern and obtain the residual which containing non-linear information.

S2.1: Differencing the original time series of the sampled power pack to obtain a smoothed time series;

S2.2: ARIMA model identification:

Plotting the autocorrelation function and partial autocorrelation function plots of the smoothed time series; obtaining a sensory awareness of the autoregressive order n and moving average order m of the ARIMA model based on the autocorrelation function and partial autocorrelation function plots; obtaining the model order (n, m) computationally using the Akaike Information Criterion criterion and the Bayesian Information Criterion.

S2.3: Hyperarameter estimation: using the least squares method to estimate the hyperparameters of the ARIMA model.

S2.4: ARIMA model validation: testing the residual and discerning whether the residual is a white noise time series, i.e. whether it satisfies a random normal distribution and is not autocorrelated.

S2.5: Using ARIMA model to forecast the time series with linear variation pattern.

S2.6: Differentiating the original time series of the power pack from the linear predictions to obtain the residual e(t) containing the non-linear variation pattern;

S3: Using the ANN model to forecast the nonlinear part and obtain predictions.

S3.1: The core set of attributes is used as input and the residual e(t), which contains the non-linear pattern of variation, obtained using the ARIMA model, is used as output to obtain the training and test sets.

S3.2: Data normalisation processing to prevent order-of-magnitude impacts.

S3.3: Establishing an ANN model, training and testing the model.

S3.4: Evaluating the performance of the ANN model.

S3.5: Using the ANN model to forecast the nonlinear part and obtain predictions e′(t).

S4: Obtaining the predictions for the linear and non-linear components using the ARIMA model and the ANN model respectively, and summing the predictions of the two components to obtain the predictions for the power pack.

S4.1: Using the ARIMA model alone to forecast the single parameter of the extracted core set of attributes and obtain the predictions, evaluating the prediction errors.

S4.2: Using the ANN model alone to forecast the single parameter of the extracted core set of attributes and obtain the predictions, evaluating the prediction errors.

S4.3: Using the hybrid prediction model to forecast the single parameter of the extracted core set of attributes and obtain the predictions, evaluating the prediction errors.

The evaluation indicators contain: mean absolute error, mean square error and mean absolute percentage error.

Mean absolute error is the average of the absolute values of the deviations of all individual observations from the arithmetic mean, which avoids the problem of errors cancelling each other out and therefore accurately reflects the magnitude of the actual prediction error.

Mean squared error is the mathematical expectation of the square of the difference between one estimate of the overall parameter determined from a subsample, reflecting a measure of the degree of difference between the estimate and the estimated quantity, and can also be obtained as a standard error, again to measure the deviation of the observation from the true value.

Mean absolute percentage error is the value of the average percentage deviation of the predicted outcome from the true outcome, which is a percentage value and therefore easier to understand than other statistics.

S4.4: Comparing the prediction errors of the three models, selecting the predictions of the hybrid prediction model as the final result.

S5: Using the parallel parameters of the core attributes combined with upper and lower limits warning to monitor the operating status of the power pack and obtain the status monitoring results;

S5.1: Calculating the upper and lower limits of the extracted set of core attributes.

S5.2: Using the ANN model to forecast the time series of the parallel parameters of the core attributes of the power pack and obtain the predictions of the parallel parameters of the core attributes, comparing the predictions with the upper and lower limits and evaluating prediction errors.

S5.3: Using the hybrid prediction model to forecast the time series of the parallel parameters of the core attributes of the power pack and obtain the predictions of the parallel parameters of the core attributes, comparing the predictions with the upper and lower limits and evaluating prediction errors.

S5.4: Obtaining the comparison results and confirming that using the hybrid prediction model and the parallel parameters of the core attributes in combination with the upper and lower limits can reduce the false alarm rate of the power pack effectively.

Using ANN model and ARIMA-ANN model described above to forecast the parallel parameters of the core attributes contain the following:

(1) The reason that the predictions of the ARIMA model is not used to compare the predictions for the parallel parameters of the core attributes is that ARIMA forecasting the time series with the linear change pattern and is only suitable for forecasting the time series of the single-parameter.

(2) The predictions using the ARIMA-ANN model were compared with those using the ARIMA model and the ANN model for the single parameter of the core attributes, and it was found that the ARIMA-ANN model has higher accurate predictions than the single model.

(3) Using the ARIMA-ANN model to forecast the trend of the operating state of the parallel parameters of the core attributes, and the predictions were compared with the predictions of the trend of the operating state of the single parameter of the core attributes using the ARIMA-ANN model, and it was found that the monitoring effect using the parallel parameters of the core attributes has higher accurate.

The present invention has the following advantageous effects:

Extracting the characteristic parameters of the power pack of complex equipment and obtaining the core set of attributes that can express the attributes of the power pack, and treating the core attributes set as a time series consisting of two parts of time series with linear and non-linear variation patterns together. Using the ARIMA model to forecast the linear part and obtaining predictions, the residual e(t) which containing the nonlinear change pattern. Using the ANN model to forecast the residual e(t) and obtaining predictions with non-linear variation change patterns, the predictions of the power pack are obtained by summing the predictions of the non-linear component with the linear component. And based on the obtained hybrid fault prediction model, using the parallel parameters of the core attributes combined with upper and lower limits warning to monitor the operating status of the power pack and obtain the status monitoring results, and confirming that using the hybrid prediction model and the parallel parameters of the core attributes in combination with the upper and lower limits can reduce the false alarm rate of the power pack effectively.

### DESCRIPTION OF DRAWINGS

FIG. 1 shows an overall flow diagram of the fault prediction method of the present invention based on the hybrid prediction model;

FIG. 2 shows a flow diagram of the ARIMA model fault prediction of the present invention;

FIG. 3 shows a flowchart of the ANN model fault prediction of the present invention;

FIG. 4 shows an overall flow diagram of the hybrid prediction model based on the present invention combined with the parallel parameters of the core attributes.

### DETAILED DESCRIPTION

Detailed description of the present invention is described below in detail in combination with accompanying drawings and technical solutions.

The present invention provides a method for predicting faults in power pack of complex equipment based on a hybrid prediction model, the prediction method being directed at operational data under steady-state conditions of the complex equipment. The hybrid prediction model is a fault prediction model consisting of a combination of the Autoregressive Integrated Moving Average (ARIMA) model and Artificial Neural Network (ANN) model.

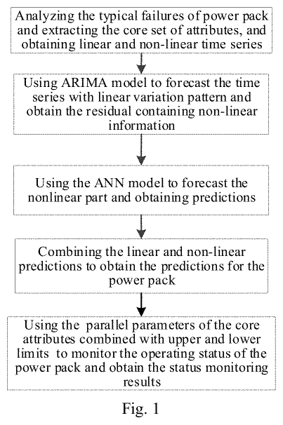

As shown in FIG. 1, the fault prediction method of the present invention comprises the following steps:

S1: Analyzing the typical failure modes of complex equipment power pack and extracting the core attributes of the evaluation indicators of complex equipment power pack, and using the rough set based difference matrix to obtain the core attributes set, and dividing the time series X of the obtained core attributes into a linear part Lt and a non-linear part Nt.

S2: Using the ARIMA model to forecast the linear part Lt and obtain the predictions L′t and its residual e(t) from the original data series, which implies the information of the non-linear time series.

S3: Using the ANN model to forecast the residual e(t), which contains information about the non-linear time series, and obtain the predictions e′(t).

S4: The predictions of the obtained linear and non-linear time series are summed to obtain the final predictions of the power pack, i.e., X′=e′(t)+L′t.

S5: Using the hybrid prediction model and the parallel parameters of the core attributes combined with upper and lower limits warning to monitor the operating status of the power pack and obtain the status monitoring results;

In this embodiment, analyzing typical failure modes of complex equipment power pack to obtain five scenarios, including: power supply pack state normal, ±15V power pack hidden state, power supply 26V01 hidden state, power supply 26V02 hidden state, main power supply 26V hidden state.

In this embodiment, the present invention obtains the core set of attributes of the power pack, as follows, the difference matrix M. In this embodiment, the present invention obtains the core set of attributes of the power pack, the difference elements in the difference matrix M(T) are a set consisting of conditional attributes, and as there are lots of difference elements in this difference matrix, they are represented by letters kᵢ for convenience of representation.

| U | x₁ | x₂ | x₃ | x₄ | x₅ | x₆ | x₇ | x₈ | x₉ | x₁₀ | x₁₁ | x₁₂ | x₁₃ | x₁₄ | x₁₅ | x₁₆ | x₁₇ | x₁₈ | x₁₉ | x₂₀ | D |
|---|---|---|---|---|---|---|---|---|---|---|---|---|---|---|---|---|---|---|---|---|---|
| x₁ | 0 | | | | | | | | | | | | | | | | | | | | 1 |
| x₂ | 0 | 0 | | | | | | | | | | | | | | | | | | | 1 |
| x₃ | 0 | 0 | 0 | | | | | | | | | | | | | | | | | | 1 |
| x₄ | 0 | 0 | 0 | 0 | | | | | | | | | | | | | | | | | 1 |
| x₅ | k₁ | k₁₄ | k₂₃ | k₃₉ | 0 | | | | | | | | | | | | | | | | 2 |
| x₆ | k₂ | Ø | k₂₄ | Ø | 0 | 0 | | | | | | | | | | | | | | | 2 |
| x₇ | k₃ | Ø | k₂₅ | Ø | 0 | 0 | 0 | | | | | | | | | | | | | | 2 |
| x₈ | k₄ | k₁₅ | k₂₆ | k₄₀ | 0 | 0 | 0 | 0 | | | | | | | | | | | | | 2 |
| x₉ | k₅ | k₁₆ | k₂₇ | k₄₁ | k₄₈ | k₆₀ | k₆₇ | k₇₄ | 0 | | | | | | | | | | | | 3 |
| x₁₀ | k₆ | Ø | k₂₈ | Ø | k₄₉ | Ø | Ø | k₇₅ | 0 | 0 | | | | | | | | | | | 3 |
| x₁₁ | k₇ | Ø | k₂₉ | Ø | k₅₀ | Ø | Ø | k₇₆ | 0 | 0 | 0 | | | | | | | | | | 3 |
| x₁₂ | Ø | k₁₇ | k₃₀ | k₄₂ | k₅₁ | k₆₁ | k₆₈ | k₇₇ | 0 | 0 | 0 | 0 | | | | | | | | | 3 |
| x₁₃ | k₈ | k₁₈ | k₃₁ | k₄₃ | k₅₂ | k₆₂ | k₆₉ | k₇₈ | k₈₅ | k₉₂ | k₉₇ | k₁₀₂ | 0 | | | | | | | | 4 |
| x₁₄ | k₉ | k₁₉ | k₃₂ | k₄₄ | k₅₃ | k₆₃ | k₇₀ | Ø | k₈₆ | k₉₃ | k₉₈ | k₁₀₃ | 0 | 0 | | | | | | | 4 |
| x₁₅ | k₁₀ | k₂₀ | k₃₃ | k₄₅ | k₅₄ | k₆₄ | k₇₁ | k₇₉ | Ø | k₉₄ | k₉₉ | k₁₀₄ | 0 | 0 | 0 | | | | | | 4 |
| x₁₆ | k₁₁ | Ø | k₃₄ | Ø | k₅₅ | Ø | Ø | k₈₀ | k₈₇ | Ø | Ø | k₁₀₅ | 0 | 0 | 0 | 0 | | | | | 4 |
| x₁₇ | Ø | Ø | k₃₅ | Ø | k₅₆ | Ø | Ø | k₈₁ | k₈₈ | Ø | Ø | k₁₀₆ | k₁₀₈ | k₁₁₂ | k₁₁₆ | Ø | 0 | | | | 5 |
| x₁₈ | k₁₂ | k₂₁ | k₃₆ | k₄₆ | k₅₇ | k₆₅ | k₇₂ | k₈₂ | k₈₉ | k₉₅ | k₁₀₀ | Ø | k₁₀₉ | k₁₁₃ | k₁₁₇ | k₁₂₀ | 0 | 0 | | | 5 |
| x₁₉ | k₁₃ | Ø | k₃₇ | Ø | k₅₈ | Ø | Ø | k₈₃ | k₉₀ | Ø | k₉₃ | k₁₀₇ | k₁₁₀ | k₁₁₄ | k₁₁₈ | Ø | 0 | 0 | 0 | | 5 |
| x₂₀ | Ø | k₂₂ | k₃₈ | k₄₇ | k₅₉ | k₆₆ | k₇₃ | k₈₄ | k₉₁ | k₉₆ | k₉₄ | Ø | k₁₁₁ | k₁₁₅ | k₁₁₉ | k₁₂₁ | 0 | 0 | 0 | 0 | 5 |

When the values of the decision attributes are different:

(1) The first case is that, firstly, the conditional attributes that make xᵢ and xⱼ (j≠j) obtain different values, which constitute the difference elements mᵢⱼ. The meaning is that in this set of conditional attributes, any one of the conditional attributes can distinguish xᵢ from xⱼ, so take one of them, and the relation is called the disjunction relation “V”, taking x₁ and x₅ as an example, the conditional attributes that distinguish x₁ from x₅ are c₅, c₆, c₇, c₈, and any one of them can distinguish x₁ from x₅, so take one of them, and it is called the disjunction relation, as c₅Vc₆Vc₇Vc₈; secondly, the only one that can distinguish x₁ from x₆ is c₅.

Then the elements that can distinguish (x₁, x₅ and x₆) are c₅ and (c₅Vc₆Vc₇Vc₈) simultaneously. This logical relation is called conjunction and it is written as: c₅ ∧(c₅Vc₆Vc₇Vc₈).

2) The other opposite case is where the unconditional attributes distinguish between xᵢ and xⱼ taking values, in which case it is the empty set.

Two cases can be disregarded when the decision attributes are the same.

3) The first case is where the elements on the main diagonal of the difference matrix are equal, i.e., Uᵢ=Uⱼ.

4) The other case is where the conditional attributes do not have the ability to make the decision attributes distinguishable regardless of whether they take the same value or not.

In this embodiment, the difference matrix for both cases in steps 3) and 4) is the empty set Ø instead of 0.

In this embodiment, the conditional attributes C consists of 13 evaluation indicators of the power pack, i.e. C=cᵢ=1, 2, . . . , 13), and xᵢ and xⱼ are sampled historical data of the complex equipment power pack. The decision attribute D is a typical failure modes set of the complex equipment power pack and containing five modes: power supply state normal set to 1, ±15V power supply hidden state set to 2, power supply 26V01 hidden state set to 3, power supply 26V02 hidden state set to 3 and main power supply 26V hidden state set to 5, i.e. D=(1,2,3,4,5).

Thus the conditional attributes that separate all individuals xᵢ and xⱼ should satisfy the “conjunction” of the differential elements of all columns, and the conjunction of all differential elements also determine ƒM(T).

The specific kᵢ representation elements are as follows.

k₁=k₂₃=k₂₄˜k₂₉=k₃₂˜k₃₅=k₃₇=k₅₁=k₅₃=k₅₇=k₅₈=k₅₉=c₅, c₆, c₇, c₈;

k₂=k₃=k₄=k₅=k₆=k₇=k₉=k₁₁ k₁₂ k₁₁=k₁₃=k₁₅ k₁₇=k₁₉=k₂₁=k₂₂=k₄₀=k₄₂=k₄₄=k₄₆=k₄₇=k₆₁=k₆₃ k₆₅ k₆₆=k₆₈=k₇₀=k₇₂=k₇₃=k₇₅=k₇₆=k₇₇=k₈₀=k₈₁=k₈₂=k₈₃=k₈₄=k₉₃=k₉₅=k₉₆=k₉₈=k₉₉=k₁₀₀=k₁₀₁=k₁₀₂=k₁₀₃=k₁₀₅=k₁₀₆=k₁₀₇=k₁₁₂=k₁₁₃=k₁₁₄=k₁₁₅=k₁₂₀=k₁₂₁=c₅;

k₁₆=k₂₀=k₄₁=k₄₅=k₆₀=k₆₄=k₆₇=k₇₁=k₈₇=k₈₈=k₉₀=k₉₄=k₉₉=k₁₁₆=k₁₁₈=c₈;

k₅=k₁₀=k₃₁=k₇₄=k₇₉=k₈₆=k₈₉=k₉₁=k₁₁₉=c₅, c₈;

k₈=k₇₈=k₁₀₉=k₁₁₁=c₅, c₆, c₇;

k₄₃=k₅₄=k₆₂=k₆₉=k₉₂=k₉₇=k₁₀₂=k₁₁₁=c₆, c₇;

k₁₄=k₃₀=k_{38,39}=k_{48,50}=k₅₂=k_{55,56}=k₅₈=k₈₅=c₆, c₇, c₈;

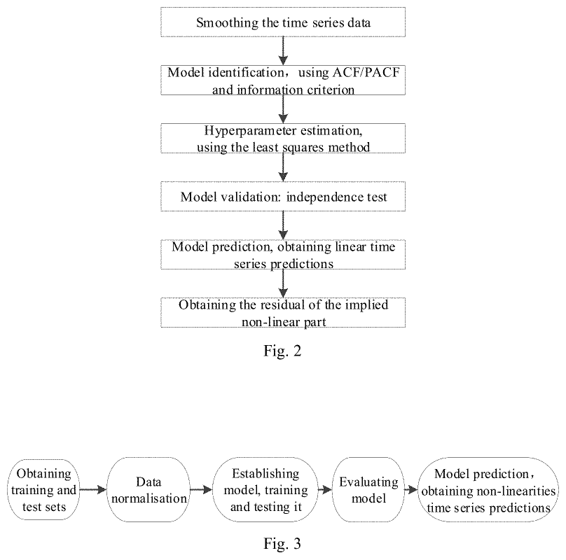

As shown in FIG. 2, using ARIMA model to forecast the linearly varying time series, it includes the following steps:

S1: smoothing the original time series of the sampled power pack.

In the embodiment, in step S1, smoothing the original time series of the sampled power pack, specifically, the first order difference is used to smooth the unsteady time series data acquired due to running in a complex environment in the field and the processed time series need to pass the ADF test and the KPSS test.

S2: ARIMA model identification:

Plotting the autocorrelation function and partial autocorrelation function plots of the smoothed time series; obtaining a sensory awareness of the autoregressive order n and moving average order m of the ARIMA model based on the autocorrelation function and partial autocorrelation function plots; obtaining the model order (n, m) computationally using the Akaike Information Criterion and the Bayesian Information Criterion.

S3: Hyperarameter estimation: using the least squares method to estimate the hyperarameter of the ARIMA model.

S4: Model validation: testing the residual and discerning whether the residual is a white noise time series, i.e. whether it satisfies a random normal distribution and is not autocorrelated.

In this embodiment, in step S4, the purpose of testing the residual is to ensure that the order of the model is appropriate, the residual is the difference between the original time series and the time series fitted by the model, it includes the following steps:

1) In the graph of the results of the residual test. The purpose of standardising the residual is to see if the residual is close to a normal distribution, and ideally the residual should be close to a normal distribution.

2) The autocorrelation and partial autocorrelation of the residual is tested based on the autocorrelation function (ACF) plot and the partial autocorrelation function (PACF) plot, generally, there are no points outside the boundaries.

3) To test whether the residual is close to a normal distribution, ideally, the input sample quantile should be close to the standard normal quantile.

S5: Using ARIMA model to forecast the time series with linear variation pattern.

In the embodiment, in step S5, using the ARIMA model that has been determined to forecast the time series with linear variation pattern, and the ratio of the amount of data using training data to test data is 3:1;

S6: Differentiating the original time series of the power pack from the linear predictions to obtain the residual e(t) containing the non-linear variation pattern;

In the embodiment, in step S6, the obtained residual e(t) containing the non-linear variation pattern e(t)=ƒ(e(t−1), e(t−2), . . . e(t-n))+a(t);

The above a(t) is the random error.

As shown in FIG. 3, using the ANN model to forecast the time series with non-linear variation pattern and obtain predictions, it includes the following steps.

S1: The core set of attributes is used as input and the residual e(t), which contains the non-linear pattern of variation, obtained using the ARIMA model, is used as output to obtain the training and test sets.

In the embodiment, in step S1: the ratio of the amount of data using training data to test data is 3:1.

S2: Data normalisation processing to prevent order-of-magnitude impacts.

S3: Establishing an ANN model, training and testing the model.

In the embodiment, in step S3: establishing the ANN model, which includes the following steps.

1) Establishing a neural network with three inputs, three outputs and four hidden layers.

2) Setting the number of iterations of the model to 1000, the training target=le-6, and the learning rate=0.01.

3) Training the network, conducting simulation tests with the trained ANN model and renormalization of the predicted data.

S4: Evaluating the performance of the ANN model.

In the embodiment, in step S4, evaluating model performance, the evaluation indicators contain: mean absolute error, mean square error and mean absolute percentage error.

Mean absolute error is the average of the absolute values of the deviations of all individual observations from the arithmetic mean, which avoids the problem of errors cancelling each other out and therefore accurately reflects the magnitude of the actual prediction error.

mean squared error is the mathematical expectation of the square of the difference between one estimate of the overall parameter determined from a subsample, reflecting a measure of the degree of difference between the estimate and the estimated quantity, and can also be obtained as a standard error, again to measure the deviation of the observation from the true value.

mean absolute percentage error is the value of the average percentage deviation of the predicted outcome from the true outcome, which is a percentage value and therefore easier to understand than other statistics.

S5: Using the ANN model to forecast the nonlinear part and obtain predictions e′(t).

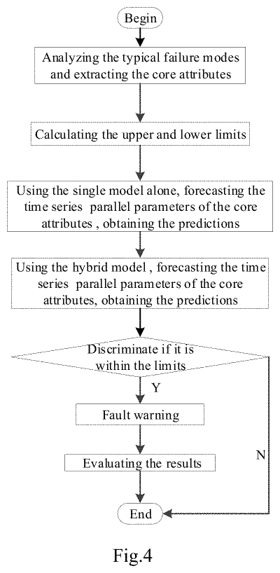

As shown in FIG. 4, using the parallel parameters of the core attributes combined with upper and lower limits warning to monitor the operating status of the power pack and obtain the status monitoring results, it includes the following steps:

S1: Analyzing the typical failure modes and extracting the core attributes, and extracting the core attributes set based on the attribute reduction method of the rough set based difference matrix set.

In the embodiment, in step S1, an attribute reduction method based on the rough set based difference matrix, it includes the following steps:

1) Calculating the difference matrix M(T) based on the definition of the difference matrix.

2) Calculating the difference function ƒM(T) based on the obtained difference matrix M(T).

3) Based on ƒM(T) in (2), using the minimal disjunction paradigm to reduce the attributes and obtain the core set of attributes.

S2: Calculating the upper and lower limits of the core set of attributes extracted by the attribute reduction method of the rough set based difference matrix, evaluating the prediction errors.

1) The upper and lower limits of the core set of attributes are as following: upper limit=standard value+one tenth of the standard value and lower limit=standard value−one tenth of the standard value.

2) The evaluation indicators contain: mean absolute error, mean square error and mean absolute percentage error.

S3: Using the ANN model to forecast the time series of the parallel parameters of the core attributes of the power pack and obtain the predictions of the parallel parameters of the core attributes, comparing the predictions with the upper and lower limits and evaluating prediction errors.

In the embodiment, using the ANN model alone to forecast the time series of the parallel parameters of the core attributes of the power pack and obtain the predictions of the parallel parameters of the core attributes, comparing the predictions with the upper and lower limits and evaluating prediction errors, it includes the following steps.

1) Using the ANN model that has been trained to forecast the parallel parameters of the core attributes that have been extracted.

2) Calculating the upper and lower limits of the core set of attributes, the effective values=standard value±one tenth of the standard value, and exceeding the effective values means exceeding the limits.

3) Using the ANN model that has been trained to forecast the single parameter of the core attributes that has been extracted.

4) Comparing the predictions of the single parameter of the core attributes with the effective values to obtain an early warning indication of whether the predictions are out of bounds.

5) Finding that using the single parameter of the core attributes to monitor condition gave an early warning signal, but not for condition monitoring using the parallel parameters of the core attributes.

6) Evaluating the prediction errors.

S4: Using the hybrid prediction model ARIMA-ANN to forecast the time series of the parallel parameters of the core attributes of the power pack and obtain the predictions of the parallel parameters of the core attributes, comparing the predictions with the upper and lower limits and evaluating prediction errors.

In the embodiment, using the ARIMA-ANN model to forecast the time series of the parallel parameters of the core attributes of the power pack and obtain the predictions of the parallel parameters of the core attributes, comparing the predictions with the upper and lower limits and evaluating prediction errors, it includes the following steps.

1) Using the ARIMA-ANN model that has been trained to forecast the parallel parameters of the core attributes that have been extracted.

2) Calculating the upper and lower limits of the core set of attributes, the effective values=standard value±one tenth of the standard value, and exceeding the effective values means exceeding the limits.

3) Using the ARIMA-ANN model that has been trained to forecast the single parameter of the core attributes that has been extracted.

4) Comparing the predictions of the single parameter of the core attributes with the effective values to obtain an early warning indication of whether the predictions are out of bounds.

5) Finding that using the single parameter of the core attributes to monitor condition gave an early warning signal, but not for condition monitoring using the parallel parameters of the core attributes.

6) Evaluating the prediction errors.

S5: By comparing the error evaluation indicators of the ANN model alone with those of the hybrid prediction model ARIMA-ANN, it can be obtained that the prediction accuracy of the hybrid prediction model is higher than that of the single model; by comparing the condition monitoring results of the single parameter of the core attributes with those of the parallel parameters of the core attributes, it can be obtained that the condition monitoring method using the parallel parameters of the core attributes can significantly reduce the false alarm rate of the power pack.

1. A method for predicting faults in power pack of complex equipment based on a hybrid prediction model, the prediction method being directed at operational data under steady-state conditions of the complex equipment, wherein:
the hybrid prediction model is a fault prediction model consisting of a combination of the Autoregressive Integrated Moving Average (ARIMA) model and Artificial Neural Network (ANN) model;
the ARIMA model is used to forecast the time series with a linear variation pattern of power pack;
the ANN model is used to forecast the time series with a non-linear pattern of variation of power pack;
the hybrid prediction model integrating the predictions of time series with a linear pattern of variation of power pack and the predictions of time series with a non-linear pattern of variation of power pack, and using parallel parameters of the core attributes for condition monitoring;
comprising steps of:
decomposing the original time series of the power pack into a linear part and a nonlinear part, using the ARIMA model to forecast the linear part and obtain predictions, and the difference between the original time series of the power pack and the linear predictions is made to obtain the residual e(t) which containing the nonlinear change pattern; using the ANN model to forecast the e(t) and obtain predictions; the predictions of the power pack are obtained by summing the predictions of the non-linear component with the linear component;
S1: analyzing the power pack failures and extracting the core set of attributes;
S1.1: establishing an evaluation indicator system for the set of attributes contained in the power pack in the complex equipment;
the complex equipment containing a power pack, a CPU board, a KZB board, an I/O board, an ADA board, an angular velocity sensor, a crosswind sensor and a tilt sensor;
S1.2: using a rough set-based difference matrix to analyze the correlations between attributes and attributes approximation;
S1.2.1: calculating the difference matrix M(T) based on the definition of the difference matrix;
S1.2.2: calculating the difference function ƒM(T) based on the obtained difference matrix M(T);
S1.3: obtaining the core set of attributes based on the minimum disjunction paradigm;
according to the difference function ƒM(T), using the minimal disjunction paradigm to reduce the attributes and obtain the core set of attributes;
S2: using ARIMA model to forecast the time series with linear variation pattern and obtain the residual which containing non-linear information;
S2.1: differencing the original time series of the sampled power pack to obtain a smoothed time series;
S2.2: ARIMA model identification;
plotting the autocorrelation function and partial autocorrelation function plots of the smoothed time series; obtaining a sensory awareness of the autoregressive order n and moving average order m of the ARIMA model based on the autocorrelation function and partial autocorrelation function plots; obtaining the model order (n, m) computationally using the Akaike Information Criterion criterion and the Bayesian Information Criterion;
S2.3: hyperparameter estimation:using the least squares method to estimate the hyperparameters of the ARIMA model;
S2.4: ARIMA model validation:testing the residual and discerning whether the residual is a white noise time series, i.e. whether it satisfies a random normal distribution and is not autocorrelated;
S2.5: using ARIMA model to forecast the time series with linear variation pattern;
S2.6: differentiating the original time series of the power pack from the linear predictions to obtain the residual e(t) containing the non-linear variation pattern;
S3: using the ANN model to forecast the nonlinear part and obtain predictions;
S3.1: the core set of attributes will be used as input and the residual e(t) containing the non-linear pattern of variation obtained through the ARIMA model will be used as output to obtain the training and test sets;
S3.2: data normalisation processing to prevent order-of-magnitude impacts;
S3.3: establishing an ANN model, training and testing the model;
S3.4: evaluating the performance of the ANN model;
S3.5: using the ANN model to forecast the nonlinear part and obtain predictions e′(t);
S4: obtaining the predictions for the linear and non-linear components using the ARIMA model and the ANN model respectively, and summing the predictions of the two components to obtain the predictions for the power pack;
S4.1: using the ARIMA model alone to forecast the single parameter of the extracted core set of attributes and obtain the predictions, evaluating the prediction errors;
S4.2: using the ANN model alone to forecast the single parameter of the extracted core set of attributes and obtain the predictions, evaluating the prediction errors;
S4.3: using the hybrid prediction model to forecast the single parameter of the extracted core set of attributes and obtain the predictions, evaluating the prediction errors;
S4.4: comparing the prediction errors of the three models, selecting the predictions of the hybrid prediction model as the final result;
S5: using the parallel parameters of the core attributes combined with upper and lower limits to monitor the operating status of the power pack and obtain the status monitoring results;
S5.1: calculating the upper and lower limits of the extracted set of core attributes;
S5.2: using the ANN model to forecast the time series of the parallel parameters of the core attributes of the power pack and obtain the predictions of the parallel parameters of the core attributes, comparing the predictions with the upper and lower limits and evaluating prediction errors;
S5.3: using the hybrid prediction model to forecast the time series of the parallel parameters of the core attributes of the power pack and obtain the predictions of the parallel parameters of the core attributes, comparing the predictions with the upper and lower limits and evaluating prediction errors;
S5.4: obtaining the comparison results and confirming that using the hybrid prediction model and monitoring the parallel parameters of the core attributes in combination with the upper and lower limits can reduce the false alarm rate of the power pack effectively.
